(19) United States
(12) Patent Application Publication
(10) Pub. No.: US 2007/0237334 A1
(43) Pub. Date: Oct. 11, 2007

(54) System and method for enhancing audio output of a computing terminal

(76) Inventors: Bruce A. Willins, East Northport, NY (US); Richard Vollkommer, Smithtown, NY (US); Joseph Katz, Stony Brook, NY (US)

Correspondence Address: FAY KAPLUN & MARCIN, LLP, 15O BROADWAY, SUITE 702, NEW YORK, NY, 10038, US

(21) Appl. No.: 11/402,080

(22) Filed: Apr. 11, 2006

(51) Int. Cl. H03G 3/20; H04R 3/00

(52) U.S. Cl. 381/57; 381/95

(57) ABSTRACT

Described is a method and system for enhancing audio output of a computing terminal. The method comprises receiving a signal corresponding to an audible output, receiving an indication of an ambient noise level in an environment into which the audible output will be output, processing the signal based on at least the indication of the ambient noise level to produce a modified signal, and outputting the modified signal.

### FIELD OF INVENTION

The present invention generally relates to methods and system for enhancing audio output of computing terminals.

### BACKGROUND

Ambient noise may be problematic for a user of a communication device in a noisy environment (e.g., city street, construction site, delivery truck, etc.). For example, the ambient noise may be combined with speech of the user when communicating with a recipient. The ambient noise distorts and/or degrades a quality of the signal making it difficult for the recipient to decipher the user's speech.

Similarly, when the communication device receives a response message, it may be inaudible and/or unintelligible due to the ambient noise and/or a distance of the user from the communication device (e.g., a far field modality). For example, when utilizing a “speaker-phone” feature, the communication device may be several feet from the user. The distance between the user and the communication device and/or the ambient noise may significantly affect a signal-to-noise ratio at the communication device (e.g., when transmitting) and at the user (e.g., when receiving). Therefore, a method of enhancing output to users of communication devices is currently desired.

### SUMMARY OF THE INVENTION

The present invention relates to a method and system for enhancing audio output of a computing terminal. The method comprises receiving a signal corresponding to an audible output, receiving an indication of an ambient noise level in an environment into which the audible output will be output, processing the signal based on at least the indication of the ambient noise level to produce a modified signal, and outputting the modified signal.

### BRIEF DESCRIPTION OF THE DRAWINGS

FIG. 1 shows an exemplary system according to an embodiment of the present invention.

FIG. 2 shows an effect of an exemplary system according to an embodiment of the present invention.

FIG. 3 shows a range of possible compression ratios according to an embodiment of the present invention.

FIG. 4 shows exemplary output and effects of a compressor according to an embodiment of the present invention.

FIG. 5 shows an exemplary method according to an embodiment of the present invention.

### DETAILED DESCRIPTION

The present invention may be further understood with reference to the following description and the appended drawings, wherein like elements are provided with the same reference numerals. The present invention discloses a system and method for enhancing an audio output of a computing terminal. An exemplary embodiment of the present invention is described with reference to a mobile computing unit modifying an output signal which includes an audible signal as a function of a level of ambient noise in a current environment of the unit (e.g., as determined from ambient noise in input signals). Those of skill in the art will understand that the present invention may also be implemented in stationary computing terminals, or any other computing device which receives and outputs audible signals.

FIG. 1 shows an exemplary embodiment of a system 2 according to the present invention. In the exemplary embodiment, a user 5 utilizes a computing device (e.g., a mobile computing unit (“MU”) 10) for conducting voice communications with a recipient 20 using a further computing device (e.g., an MU 21). Each of the MUs 10 and 21 may be any stationary or mobile computing device including communications capabilities, such as, for example, a PC, a cell phone, a laptop, a handheld computer, a PDA, or any other computing device with access to a communications network (e.g., wired/wireless LAN/WAN). Those of skill in the art will understand that the user of the MU 10 does not need to be communicating with another user to receive a return audio signal. For example, the MU 10 may be communicating with a device such as a server including an automatic speech recognition (“ASR”) engine that returns audio signals in response to the user's speech into the MU 10. Thus, the present invention may be applied to any audio signal input to and/or output by the MU 10.

The user 5 emits a sound 12 which the MU 10 converts into an input signal for transmission to the recipient 20 over the communications network. The MU 10 receives the sound 12 via one or more speakers (e.g., an array of speakers). However, as shown in FIG. 1, the user 5 may be located in an environment which is subject to an ambient noise 30. In a far-field modality, the ambient noise 30 is included in the input signal impairing a quality of the sound 12. Thus, the MU 10 may utilize a signal processing technique to reduce the ambient noise 30 (and other artifacts) in the input signal (e.g., improving a signal-to-noise ratio (“SNR”)), generating a modified input signal which is transmitted to and output by the MU 21.

As shown in FIG. 1, the recipient 20 is in a near-field modality (or a far-field modality with low or zero ambient noise). As understood by those of skill in the art, in the near-field modality ambient noise is less problematic because a sound wave generated by the recipient 20 travels a shorter distance to the MU 21, and a sound wave generated by the MU 21 travels a shorter distance to the recipient 20. Thus, the MU 21 may not need to filter a response signal (including a response 22) as much as the MU 10 needs to filter the input signal. However, when the response signal is output by the MU 10 in the far-field modality, the ambient noise 30 may drown out the output 26. That is, the SNR of the response signal may be adequate when received and output by the MU 10. But, due to the ambient noise 30, the SNR at the user 5 is significantly lower, rendering the output response 26 substantially inaudible. Thus, according to the present invention, the MU 10 may modify the response signal as a function of the ambient noise 30.

When the MU 10 is processing the input signal to enhance the quality thereof, the MU 10 may generate processing data corresponding to a level of the ambient noise 30 and/or the signal processing technique(s) used to improve the quality of the signal. The MU 10 may utilize the processing data when modifying the response signal. For example, if the user is working in a loud factory, the data may indicate that the ambient noise level (e.g., a sound pressure level (“SPL”)) is approximately 90 decibels (“dB”). Thus, the MU 10 utilizes the processing data to compensate for the ambient noise 30 (e.g., 90 dB) in the environment of the user 5. Different activities in different environments may generate corresponding SPLs as shown below by the exemplary list:

| SPL (dB) | Source |
|---|---|
| 180 | Rocket engine at 30 m |
| 150 | Jet engine at 30 m |
| 130 | Threshold of pain |
| 120 | Rock Concert |
| 110 | Chainsaw at 1 m |
| 100 | Jackhammer at 2 m |
| 90 | Loud factory |
| 80 | Inside a heavy truck |
| 70 | Busy traffic at 5 m |
| 60 | Inside a crowded restaurant |
| 50 | Inside an office |
| 40 | Residential area at night |
| 30 | Inside a theater (no talking) |
| 10 | Human breathing at 3 m |
| 0 | Threshold of human hearing |

Referring back to FIG. 1, the MU 10 may utilize one or more input signal processing techniques 14 (e.g., adaptive noise filtering, signal separation, adaptive beam steering, etc.) to reduce the ambient noise 30 and/or enhance the sound 12 in the input signal. The MU 10 may generate the processing data as a result of the signal processing techniques 14. When the response signal is received by the MU 10, the processing data may be utilized in an output signal processing technique 24 to generate an output 26 which makes the response 22 audible over the ambient noise 30.

In one exemplary embodiment, the output signal enhancement technique 24 includes amplifying small return signals, compressing return signals and supplementing them with make-up gain and/or a combination thereof. For example, the response signal may be compressed by a compressor (e.g., a coder/decoder (“CODEC”) chip) utilized by the MU 10. The CODEC chip may be, for example, an 8-bit digital audio converter utilizing a nonlinear quantization scheme known as “mu-law encoding.” However, it will be understood by those of skill in the art that any of a variety of compressors may be used, e.g., those implemented in separate chips or CODECs implemented by the main processor. The amount of compression may be controlled as a function of the processing data. Thus, a dynamic range of the response signal may be reduced and supplemented with make-up gain to reach the level of the ambient noise 30, enabling the user 5 to hear the response 22.

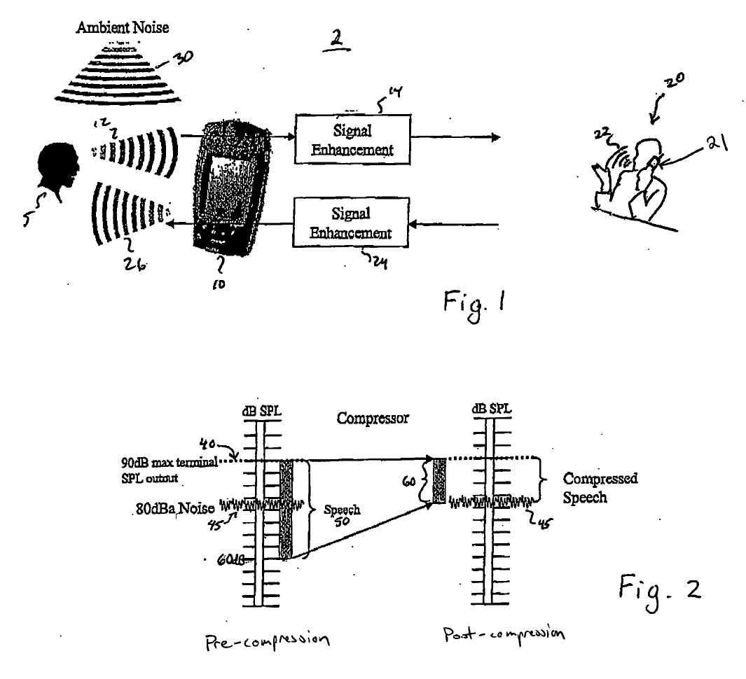

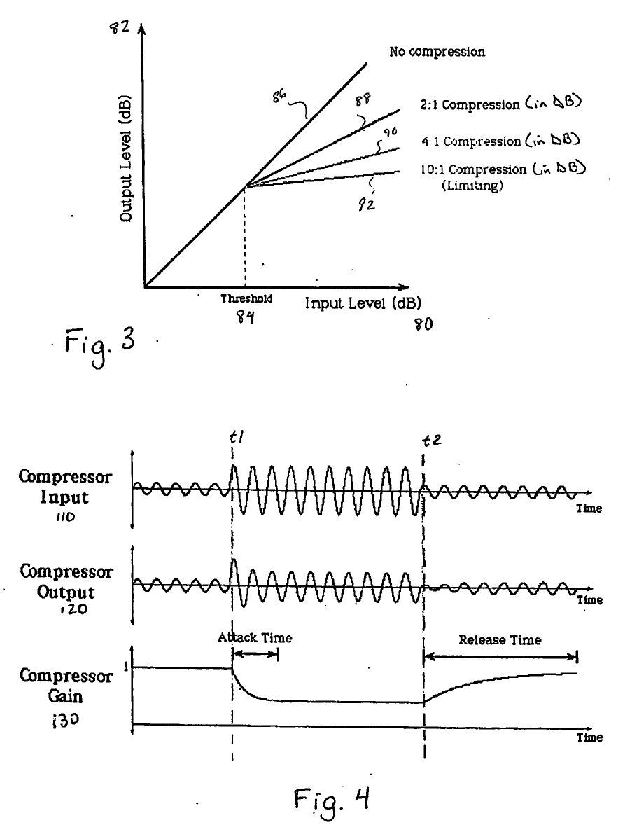

FIG. 2 illustrates an exemplary compression of the response signal according to the present invention. In the exemplary embodiment, a maximum output 40 of the MU 10 may be approximately 90 dB. Prior to compression, a dynamic range 50 of the response signal may be approximately 30 dB, having lows at 60 dB and highs at 90 dB. That is, the MU 10 may output the response signal so that the highs are output at the maximum output 40. An ambient noise level 45 is included in the processing data generated for the input signal. For example, inside a freight truck, the ambient noise level 45 may be approximately 80 dB, and thus a considerable portion of the response signal (e.g., a portion less than or equal to 80 dB) may be unintelligible to the user 5. Thus, the compressor compresses the response signal as a function of the ambient noise level 45 and the dynamic range 50. After compression, a compressed dynamic range 60 is approximately 10 dB using, for example, 3:1 compression (in dB). To compensate for the ambient noise level 45, the compressed response signal may be supplemented with the make-up gain. For example, a predetermined amount of make-up gain may be added to the compressed response signal so that the highs remain at 90 dB, but the lows are now at approximately 80 dB.

In the exemplary embodiment of FIG. 2, a 3:1 compression (in dB) was performed. That is, the dynamic range 50 of response signal was reduced from 30 dB to 10 dB. Those of skill in the art will understand that various compression ratios may be utilized. In one embodiment of the present invention, the compression ratio may vary dynamically as a function of the ambient noise level 45 measured by the MU 10.

FIG. 3 shows a graph demonstrating an effect of compression on a signal. As shown, the x-axis represents an input level 80, in dB, of a signal to the compressor, and the y-axis represents an output level 82 in dB of the signal from the compressor. FIG. 3 also shows a threshold input value 84 at which the compressor activates. An uncompressed signal, represented by line 86, maintains a proportional level of the input level 80 to the output level 82 before and after it reaches the threshold input value 84. However, compressed signals represented by lines 88, 90, 92 exhibit decreased output levels 82 after the threshold input value 84 is reached. The line 88 demonstrates an effect of 2:1 compression (in dB), whereas the line 90 demonstrates 4:1 compression (in dB), and the line 92 demonstrates 10:1 compression (in dB). A high compression ratio, such as 10:1 (in dB), may be referred to as “essentially limiting”, because the output level 82 is significantly reduced with respect to the input level 80.

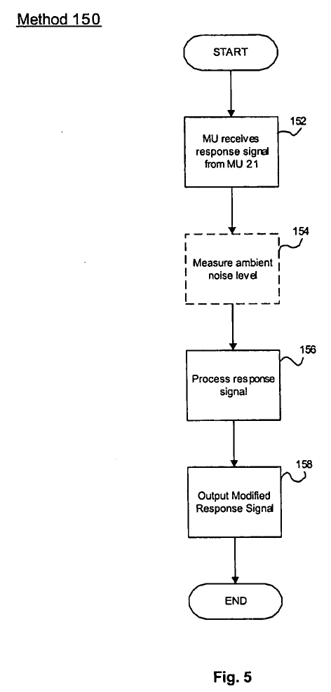

FIG. 4 further demonstrates the effects of signal compression, including reduction of a gain 130. In this example, an amplitude of an uncompressed signal 110 may increase and decrease in correlation to an event, such as an increase/decrease in the dynamic range of input. Between a time t1 and a time t2, the amplitude of the uncompressed signal 110 is at an increased level, which may represent the increase in dynamic range. Thus, at the time t1, the compressor may recognize that the input signal 110 exceeds a predetermined threshold, and thus begins compression. After compression, this increase in the dynamic range is less dramatic, as shown by compressed signal 120. At the time t2, the compressor recognizes that the dynamic range of the input signal 110 has lowered within the predefined threshold, and thus releases compression. A reaction time of the compressor in activating and releasing may be seen by a differentiated shape of the signal 120 at times t1 and t2, and more clearly by the gain 130.

As shown in FIG. 4, the compressor gain 130 is nonlinear during an attack time and a release time. The attack time is an amount of time which the compressor utilizes to respond to an increase in the dynamic range of the input signal above the threshold. It may be preferable to use a short attack time relative to a period of the input signal. That is, as the attack time approaches zero, a greater amount of distortion may result, making the compression noticeable to the user. Thus, an appropriate attack time may be approximately one or more periods of the uncompressed signal 110.

The release time is an amount of time which the compressor utilizes to increase the gain 130 when the input signal drops below the threshold. Similar to the attack time, a greater amount of distortion may result as the release time approaches zero. Thus, a release time of approximately several periods of the input signal 110 may be appropriate.

Although the compressor reduces the gain 130 when the input signal 110 is greater than the threshold, a make-up gain may be utilized to supplement the compressed signal 120. The make-up gain may be provided by any number of methods, such as, for example, the compressor including a final gain stage with a level control, adjusting the compressed signal 120 prior to output by the MU 10. In the final gain stage, the signal 120 may be supplemented with the make-up gain before being converted into the output 26 emitted from the MU 10, as shown in FIG. 1.

FIG. 5 shows an exemplary method 150 for enhancing output according to the present invention. The method 150 will be described with reference to the exemplary embodiments shown in FIGS. 1 and 2. However, it will be understood by those of skill in the art that the method 150 may be implemented on any number and/or type of communication systems.

In step 152, the MU 10 receives a signal. In the exemplary embodiment, the signal is the response signal from the recipient 20. The MU 10 may optionally measure the ambient noise level (step 154). In the above examples, it was considered that the ambient noise level was measured when the user 5 spoke into the MU 10. However, according to other exemplary embodiments of the method 150 the ambient noise level is measured subsequent to the MU 10 receiving the response signal and prior to the MU 10 processing the response signal. Thus, it will be understood by those of skill in the art that this step may be performed at various points in time. For example, in one embodiment of the present invention, the MU 10 may measure the ambient noise level prior to performing the signal enhancements 14 on the input signal corresponding to the input 12. That is, the MU 10 may measure the ambient noise level, and process the input signal as a function thereof. Accordingly, the MU 10 may perform the signal enhancements 24 as a function of that ambient noise level. In another embodiment of the present invention, the MU 10 may not measure the ambient noise level at all, as will be discussed below in step 156.

In step 156, the MU 10 processes the response signal. That is, the MU 10 performs the signal enhancements 24 (e.g., compression of the response signal) as shown in FIG. 1. For example, the compressor may reduce the dynamic range of the response signal, and, if necessary, an amount of make-up gain may be added to the compressed response signal. According to a preferred embodiment of the present invention, the response signal may be processed as a function of the ambient noise level measured by the MU 10. As mentioned previously, the MU 10 may measure the ambient noise level at various points in time (e.g., before processing the input signal, upon receipt of the response signal, etc.). A highest degree of symmetry in an exchange between the user 5 and the user 20 may occur if the MU 10 measures the ambient noise level prior to performing signal enhancements 14 on the input signal, and then performs the signal enhancements 24 on the response signal as a function of that same noise level. This way, the input 12 of the user 5 will be enhanced to the same degree as the output 26 of the MU 10.

According to another embodiment of the present invention, the MU 10 may process the response signal without measuring the ambient noise level. For example, the MU 10 may perform signal-enhancing techniques on every response signal, thereby ensuring that the output 26 is always of highest quality. Alternatively, the MU 10 may only perform the signal enhancing techniques upon a cue (e.g., activation of a trigger) from the user 5.

In step 158, the modified response signal is output to the user 5. The output 26 emitted from the MU 10 may be entirely intelligible to the user 5, because the lowest response in the dynamic range has been increased to or above the ambient noise level.

An advantage of the present invention is that low level voice signals may be increased over ambient noise without clipping or saturating a speaker. In other words, an increased output level may be provided to a user without forcing the speaker outside of its normal operating limits. Thus, a segment of speech, despite a potentially wide dynamic range including some relatively low SPL signals, may be made entirely audible to a user without damaging the speaker in the user's MU.

The present invention may prove particularly useful where the user 5 is in a far-field modality and the recipient 20 is in a near-field modality. For example, the user 5 may be utilizing a speakerphone feature of the MU 10, perhaps to enable him to rest the MU 10 on a dashboard of a forklift that he is operating in a factory. However, the recipient 20 may be a user communicating through the MU 21 held directly to his ear (e.g., a supervisor in his office giving instructions). Thus, because of a remote location of the MU 10 with respect to the user 5, a greater amount of ambient noise may interfere with input to and output from the MU 10, as compared to an amount of interference at the supervisor's end. However, according to the present invention, the user 5 may hear his supervisor's instructions over the ambient noise from the factory. Further, because the signal transmitted to the supervisor is likely enhanced to reduce noise from the user's 5 end, enhancing the signals provided to the user 5 offers greater symmetry in the communication. Accordingly, both far field users and the near field users are able to communicate more easily and efficiently.

The present invention has been described with reference to the above exemplary embodiments. One skilled in the art would understand that the present invention may also be successfully implemented if modified. Accordingly, various modifications and changes may be made to the embodiments without departing from the broadest spirit and scope of the present invention as set forth in the claims that follow. The specification and drawings, accordingly, should be regarded in an illustrative rather than restrictive sense.

What is claimed is:

1. A method, comprising:
receiving a signal corresponding to an audible output;
receiving indication data of an ambient noise level in an environment into which the audible output is to be provided;
processing the signal based on at least the indication data of the ambient noise level to generate a modified signal; and
outputting the modified signal.

2. The method of claim 1, wherein the indication data of the ambient noise level is received when a user speaks into a microphone.

3. The method of claim 1, wherein the processing includes:
amplifying the signal.

4. The method of claim 1, wherein the processing includes:
compressing the signal.

5. The method of claim 1, wherein the processing includes:
supplementing the signal with a make-up gain.

6. The method of claim 4, wherein the signal is compressed at one of a 2 to 1 compression, 4 to 1 compression and 10 to 1 compression.

7. The method of claim 4, wherein the compressing is performed only when the ambient noise level is greater than a predetermined threshold.

8. The method of claim 5, wherein the gain is nonlinear during one of an attack time and a release time.

9. A computing device, comprising:
a receiving arrangement receiving a signal corresponding to an audible output;
a processor processing the signal to generate a modified signal based on at least indication data of an ambient noise level in an environment in which the computing device is located; and
a speaker outputing a modified audible output corresponding to the modified signal.

10. The computing device of claim 9, wherein the indication data of the ambient noise level is received via the speaker.

11. The computing device of claim 9, further comprising:
an input device receiving the indication data of the ambient noise level.

12. The computing device of claim 9, wherein the computing device is one of a mobile computing device, a PDA, a mobile phone, a personal computer and a laptop computer.

13. The computing device of claim 9, wherein the processor includes a CODEC chip to process the signal.

14. The computing device of claim 9, wherein the processor processes the signal based on at least the indication data of the ambient noise level only when the computing device is in a speakerphone mode.

15. The computing device of claim 9, wherein the processing includes one of amplifying the signal, compressing the signal and supplementing the signal with a make-up gain.

16. The computing device of claim 15, wherein the compressing is performed only when the ambient noise level is greater than a predetermined threshold.

17. The computing device of claim 15, wherein the gain is nonlinear during one of an attack time and a release time.

18. The computing device of claim 9, wherein the processor processes audible signals received form a user to compensate for the ambient noise level.

19. A system comprising a memory storing a set of instructions and a processor for executing the instructions, the set of instructions configured to receive a signal corresponding to an audible output;
receive indication data of an ambient noise level in an environment into which the audible output is to be provided;
process the signal to generate a modified signal based on at least the indication data of the ambient noise level; and
output the modified signal.

20. A computing device, comprising:
receiving means for receiving a signal corresponding to an audible output;
processing means for processing the signal to produce a modified signal based on at least indication data of an ambient noise level in an environment in which the computing device is located; and
output means for outputting a modified audible output corresponding to the modified signal.
